(19) United States
(12) Patent Application Publication
(10) Pub. No.: US 2016/0284902 A1
(43) Pub. Date: Sep. 29, 2016

(54) ADHERING AN ANCAPSULANT SHEET FOR A PHOTOVOLTAIC MODULE

(71) Applicant: CENCORP OYJ, Mikkeli (FI)

(72) Inventors: Henrikki PANTSAR, Canton, MI (US); Ville LAMPINEN, Turku (FI); Timo SAVIKKO, Espoo (FI); Jarko NIEMINEN, Lohja (FI); Tuukka SAVISALO, Mikkeli (FI)

(21) Appl. No.: 14/914,187

(22) PCT Filed: Jul. 22, 2014
(86) PCT No.: PCT/FI2014/050591

§ 371 Date: Feb. 24, 2016

(30) Foreign Application Priority Data
Jul. 23, 2013 (FI) 20135790

(51) Int. Cl. H01L 31/048; B32B 3/26; B32B 27/40; B32B 27/30; H01L 31/18; H01L 31/05

(52) U.S. Cl. CPC H01L 31/048; H01L 31/1876; H01L 31/0516; B32B 27/40; B32B 27/306; B32B 3/266; B32B 2457/12; B32B 2307/412; B32B 2307/41; B32B 2307/202

(57) ABSTRACT

A method and a system for assembling a photovoltaic module (1) comprising a back sheet (2); a cover sheet (9); and a multitude of photovoltaic cells (6) between the back sheet (2) and the cover sheet (9), the photovoltaic cells (6) being separated from the back sheet (2) and the cover sheet (9) by sheets of encapsulant material (8). The method comprises using one of the back sheet (2) and the cover sheet (9) as a support sheet; heating the support sheet or parts of the support sheet to a temperature suitable for the encapsulant material (8) to adhere to the support sheet; and moving the support sheet to be in contact with one of the sheets of encapsulant material (8), causing the sheet of encapsulant material (8) to adhere to the support sheet.

### FIELD OF THE INVENTION

The invention relates to photovoltaic modules. More specifically, the invention relates to a method and a system for assembling a photovoltaic module.

### BACKGROUND OF THE INVENTION

Photovoltaic cells or solar cells are assembled together to form a photovoltaic module. Such modules are also known as solar modules or solar panels. The photovoltaic module is a large area optoelectronic device that converts the energy of light such as solar radiation directly into electricity the photovoltaic effect.

Photovoltaic modules are commonly manufactured using crystalline silicon cells that are electrically connected in series using tabs and strings. These assemblies are encapsulated to protect the assembly from environment and also to provide safe electrical connections. The top side of the assembly is generally covered with glass and the backside with a sheet of flexible polymer laminate, though glass can also be used for the back. This assembly method is difficult to fully automate and thus often involves large amounts of manual labour.

U.S. Pat. No. 5,972,732A describes a “monolithic module assembly”, a planar process that is better suited for automation. The process utilizes back contact photovoltaic cells wherein both emitter and collector contacts are on the same side of the photovoltaic cell.

The photovoltaic module comprises a back sheet, which may comprise electrically conductive circuit elements, photovoltaic cells and a cover sheet such as glass. Between the back sheet and the photovoltaic cells is a sheet of encapsulant material for securing the components and providing adhesion to the laminated structure. The sheet of encapsulant material comprises also holes for interconnecting the connection pads of the back sheet together with the contacts of the photovoltaic cells. Cells and connection pads of the back sheet are connected by conductive adhesive paste, solder paste or other conductive materials. There is also another sheet of encapsulant between the photovoltaic cells and the cover sheet.

The sheets of encapsulant material are typically made of ethylene vinyl acetate EVA, silicone or polyurethane. The typical thickness of the encapsulant sheets is less than 500 μm with the aim to use thinner sheets. The low thickness makes the mechanical strength and rigidity of the encapsulant sheets low, thereby making it very difficult to handle the encapsulant sheets by conventional vacuum grippers. The encapsulant material may shrink if it is left alone on the work plane for an extended period. It should be processed as soon as possible to prevent shrinkage.

In the assembly phase the first one of the encapsulant sheets mentioned above is dimensionally accurate, comprising precisely manufactured holes for the interconnections described above. The photovoltaic module comprises a multitude of, typically tens of, photovoltaic cells, each being e.g. 156×156 mm in size. Thus, the photovoltaic module is a large area object and the encapsulant sheet should cover the whole area. It is difficult to place and handle the thin, rubber-like encapsulant material with the required accuracy over the area of the whole module.

The correct placement of the encapsulant sheet having the interconnecting holes therein is very important as the holes in the sheet must provide correct path for the interconnections. Misplaced holes for the interconnecting paste could affect the quality of the cured connections either by increasing unnecessary electrical resistance or by completely failing to connect. One solution is to make the holes large enough to allow dimensional variation. This approach works to some extent, as long as the encapsulant sheet has sufficient mechanical strength and stability, the number of holes is relatively small and formation of voids between the encapsulant sheet and the conductive materials are prohibited. Voids may lead into diminished long term performance.

Another solution according to prior art is to use a carrier sheet to stabilize the encapsulant sheet, for example low cost film or paper. The carrier sheet has to be removed and discarded before assembling the module, thereby adding a step to the manufacturing process.

The low mechanical strength and low rigidity is problematic also for the handling of the other sheet of encapsulant to be located between the photovoltaic cells and the cover sheet, even though the placement of this sheet is not as strictly defined as the placement of the first sheet of encapsulant having the interconnecting holes therein. For example, the thin sheet of encapsulant is very susceptible to wrinkling during the handling thereof. Moreover, this basic problem is independent of the basic configuration of the photovoltaic module and applies also to the assembly of a conventional module where the electrical connections between the photovoltaic cells are made by means of tabs and strings, and where both sheets of encapsulant are plain sheets without any holes therein.

### SUMMARY

The present invention discloses a method for assembling a photovoltaic module comprising a back sheet, possibly comprising electrically conductive circuit elements, a cover sheet and a multitude of photovoltaic cells between the back sheet and the cover sheet, the photovoltaic cells being separated from the back sheet and the cover sheet by sheets of encapsulant material. The method comprises using at least one of the back sheet and the cover sheet as a support sheet, heating at least portion of the support sheet to a temperature suitable for the encapsulant material to adhere to the support sheet and moving the support sheet to be in contact with the encapsulating material, causing the encapsulant material to adhere to the support sheet. The method comprises also lifting the subassembly comprising the support sheet and the sheet of encapsulant material to the next assembly step, maintaining the relative positioning between the two components. Lifting in this context does not refer only to upward motion, but merely a movement where the encapsulant material is carried by the support sheet. The temperature range in which adhesion occurs depends on the encapsulant material used. For example, for EVA, the suitable temperature range is between 50-80° C.

In one embodiment the method comprises lifting the sheet of encapsulant material from the work plane by lifting the support sheet. In one embodiment the method comprises lifting the sheet of encapsulant material from the roller by moving the support sheet along the roller. In one embodiment the method comprises separating the sheet of encapsulant material from the supporting liner during lifting the support sheet from the roller, causing the sheet of encapsulant material to retain same dimensions as in the supporting liner.

In one embodiment the method comprises using the back sheet as the support sheet, forming a virtual map containing the assembly positions of the back sheet and the sheet of encapsulant material separating the back sheet and the plurality of photovoltaic cells, machining holes to said sheet of encapsulant material according to the virtual map and positioning the back sheet on top of the sheet of encapsulant material according to the virtual map position information. The latter embodiment, where the back sheet is used as the support sheet, applies to the assembly of a photovoltaic module where the hack sheet comprises electrically conductive circuit elements for interconnecting the connection pads of the back sheet together with the contacts of the photovoltaic cells.

Another aspect of the invention discloses a system for assembling a photovoltaic module comprising a back sheet, possibly comprising electrically conductive circuit elements, a cover sheet, and a multitude of photovoltaic cells between the back she and the cover sheet, the photovoltaic cells being separated from the back sheet and the cover sheet by sheets of encapsulant material. The system comprises means for heating at least a portion of a support sheet, using one of the back sheet and the cover sheet arranged to be used as the support sheet, to a temperature suitable for the encapsulant material to adhere to the support sheet and means for moving the support sheet to be in contact with the encapsulating material, causing the encapsulant material to adhere to the support sheet. Means for heating comprise for example a heating element, heating resistor, laser, heating lamp, infrared lamp, ultrasound, friction or heating by radiation such as ultraviolet, infrared or visible light. Means for moving comprise a robot or manipulator, manual movement limited by stopper or a moving element arranged to convey the support sheet from one assembly cell to another.

In one embodiment the system comprises means for lifting the sheet of encapsulant material from the work plane by lifting the support sheet. In one embodiment the system comprises means for lifting the sheet of encapsulant material from the roller by moving the support sheet along the roller. In one embodiment the system comprises means for separating the sheet of encapsulant material from the supporting liner during lifting the support sheet from the roller, causing the sheet of encapsulant material to retain same dimensions as in the supporting liner.

In one embodiment where the back sheet is used as the support sheet, the system comprises means for forming a virtual map comprising the assembly positions of the back sheet and the sheet of encapsulant material separating the back sheet and the plurality of photovoltaic cells, means for machining holes to said sheet of encapsulant material to positions according to the virtual map and means for positioning the back sheet on top of the sheet of encapsulant material according to the virtual map position information. The latter embodiment, where the back sheet is used as the support sheet, applies to the assembly of a photovoltaic module where the back sheet comprises electrically conductive circuit elements for interconnecting the connection pads of the back sheet together with the contacts of the photovoltaic cells. Means for forming the virtual map comprise for example CAD software, a camera detection or scanning element arranged to detect the positions of markers or fiducials in a component of the assembly.

The virtual map may comprise all or portion of the components of the assembly, the cover sheet, at least one encapsulant sheet and the positioning of holes and the sheet itself, positions of contacts or conductive circuit elements in the back sheet and the properties of the interconnecting paste, such as the amount, the position or the shape. In one embodiment the virtual map comprises the form of the component in a flat plane and the positioning information, of the contact pads.

The embodiments of the invention described hereinbefore may be used in any combination with each other. Several of the embodiments may be combined together to form a further embodiment of the invention. A method, an apparatus, a system or a computer program to which the invention is related may comprise at least one of the embodiments of the invention described hereinbefore. It is to be understood that any of the above embodiments or modifications can be applied singly or in combination to the respective aspects to which they refer, unless they are explicitly stated as excluding alternatives.

The present invention utilizes the heated support sheet to handle the sheet of encapsulant material. The invention allows in general safer handling of the sheets of encapsulant. In particular, in the case of a back sheet comprising electrically conductive circuit elements and the lower sheet of encapsulant comprising holes for interconnecting the connection pads of the back sheet together with the contacts of the photovoltaic cells, the present invention allows more precise tolerances enabling more accurate features in the electrical connections of the module. Improved handling of thin encapsulant material leads to better positional accuracy over the whole area of the module and less deformation of the sheet.

Further, the ability to maintain the geometry of the encapsulant sheet helps the assembly process and enables the use of thinner encapsulant sheets without compromising dimensional stability. This leads to reduction of materials in the encapsulant. In the case of back contact modules the use of thinner encapsulant sheet leads to corresponding reduction of the interconnecting paste, and higher efficiency due to reduction of resistive losses in the interconnections.

The present invention is suitable for assembling back contact solar modules, H-pattern solar modules, crystalline based solar modules or any other solar module structure using the encapsulant material in the sheet form. Dimensions of the encapsulant sheet remain constant and the sheet is easy to manipulate; shrinkage, wrinkling, distortion, elongation are avoided.

### BRIEF DESCRIPTION OF THE DRAWINGS

The accompanying drawings, which are included to provide a further understanding of the invention and constitute a part of this specification, illustrate embodiments of the invention and together with the description help to explain the principles of the invention. In the drawings:

FIG. 1 is a block diagram illustrating an exemplary embodiment,

FIG. 2 illustrates the device elements according to the invention,

FIG. 3 illustrates the assembly of the photovoltaic module and the handling of the sheets of encapsulant therein,

FIG. 4 illustrates an example of a virtual map, and

FIG. 5 illustrates an example of lifting the sheet of encapsulant material from the roller.

### DETAILED DESCRIPTION OF THE INVENTION

Reference will now be made in detail to the exemplary embodiments of the present invention, examples of which are illustrated in the accompanying drawings.

The photovoltaic module according to the present invention is an assembly comprising several photovoltaic cells that are connected together to increase the amount of power when exposed to light. The assembly usually comprises laminating the components to form a flat and rigid structure. An example of the photovoltaic module is a large flat sandwich structure, comprising a back sheet, an encapsulant layer to produce adherence, rigidity and insulation between lavers, photovoltaic cells electrically connected and arranged to be an array, another encapsulant layer for insulation and adherence, and a transparent front sheet such as glass plate. In this document, the terms “front sheet”, “front sheet panel”, and “cover sheet” are all used to refer to the same element of a photovoltaic module. Similarly, “encapsulant layer” and “sheet of encapsulant material” refer to the same element. In one example the size of one photovoltaic cell is 156×156 mm, wherein the total number of such cells may be for example 30, 36, 48, 60 or 72 in a single module.

According to the exemplary embodiment the back sheet is used to handle the sheet of encapsulant material on the assembly line. According to another exemplary embodiment the cover sheet is used to handle the sheet of encapsulant material. This eliminates the need for additional support sheets and related waste, yet provides the required support and dimensional stability throughout the assembly process. The photovoltaic module may comprise two sheets of encapsulant material. The second sheet of encapsulant material is arranged between the cover sheet such as glass and the multitude of photovoltaic cells. The first sheet of encapsulant material is arranged between the multitude of photovoltaic cells and the back sheet. In the following example the invention is explained for the embodiment where the sheet of encapsulant material is arranged between the multitude of photovoltaic cells and the back sheet. The same principle may be applied to the cover sheet.

The sheet of encapsulant material requires that holes are arranged to predetermined positions. The holes are machined in an assembly cell in which the encapsulant foil is temporarily fixed onto a work plane or any fixed support, such as vacuum table. The holes are machined to match the locations of interconnect paste in the completed module with appropriate tolerances to ensure a good fit. The holes can be machined using mechanical cutters, heat or irradiation such as laser beam. The cutting residuals may be removed by vacuuming or by vaporization.

A manipulator is configured to pick up the back sheet in a manner that the location and the geometry of the back sheet are known, for example in the virtual map. Also the location of each contact point or pad is defined. The points are arranged to match with the holes on the encapsulant foil. The manipulator delivers the back sheet to the position from which the encapsulant material is picked up from. The holes in the encapsulant are positioned to align with the locations of the contact pads in the back sheet, for example using the information from the virtual map.

The manipulator applies heat to the whole hack sheet or to the selected locations of the hack sheet. Pressure and heat are applied to join the back sheet and the encapsulant sheet together. In one embodiment the adherence is partial; only selected locations are subjected to the adherence. In one embodiment the hack sheet and the encapsulant she are adhered together over the whole common area.

Without releasing the grip from the back sheet, both the back sheet and the encapsulant sheet are delivered to a second assembly cell by the manipulator. In the second assembly cell the photovoltaic cells receive the interconnecting paste for example by printing directly to the photovoltaic cell. The photovoltaic cell is positioned on a cover sheet such as glass, with a sheet of second encapsulant material in between. Positions of all interconnecting paste cakes are defined according to the virtual map information. The manipulator aligns the two subassemblies and presses them together while applying heat and pressure. The completed pre-laminate is delivered to a laminating process using the manipulator.

In one example the sheet of encapsulant material is applied to the back sheet from a reel. The material is stored on a reel and pulled onto another reel for machining. The virtual map information is used to machine the encapsulant sheet to the desired shape directly on the reel. The heated back sheet is rolled over the reel to enable the adherence.

The assembly process may start either from the back sheet or from the transparent front sheet. The back sheet is pre-fabricated, comprising one or more protective layers. Examples of such layers are a layer of polyvinyl fluoride and a carrier film commonly made of polyethylene terephthalate, PET. The back sheet also comprises electrically conductive circuit elements that provide the interconnections between photovoltaic cells.

The interconnecting paste is applied to the contact points of the back sheet or the photovoltaic cell for example by printing. In one example the encapsulant sheet is applied to the back sheet before the interconnecting paste; in another example the interconnecting paste is applied before attaching the encapsulant sheet.

The paste contains metal particles, such as silver, forming after the marina process a solid conductor between the cell contacts, either front or back, and the conductive circuit elements on the back sheet. Back contact photovoltaic cells are positioned onto the assembly, aligning to the holes in the sheet of encapsulant material and the interconnecting paste.

As an alternative to a curable interconnection paste described above, also soldering paste can be used for the interconnections, in which case the final contacts between the cell contacts and the circuit elements of the back sheet are formed in a soldering process at an elevated temperature.

The conductive circuit elements are in one embodiment separate components that are arranged on the first sheet of encapsulant material, being supported by the back sheet and providing electrical connections through the holes in the first sheet of encapsulant material. The conductive circuit elements may be placed on the first sheet of encapsulant material on the predefined positions. The heated back sheet is used to grab both the assembly comprising conducive circuit elements and the sheet of encapsulant material for example from the work plane.

The second sheet of encapsulant material is placed on top of the layer of photovoltaic cells and the cover sheet on the sheet of encapsulant material. The cover sheet is for example made of glass. The assembly according to this process may need to be turned around to be laminated, with the cover sheet facing down. Before turning the assembly it may require a preheating step to secure the assembled components.

According to one example a virtual map is formed from the data of the pre-fabricated back sheet. In the beginning the data of all assembly steps are present, comprising an ideal situation, where all components are positioned without any deformation or variations of the real manufacturing process. The back sheet is measured from selected reference points or common measurable points. Examples of the reference points are outer edges or corners of the back sheet; the electrical conductors or contact pads that are configured to receive the interconnecting paste; fixed components on the sheet; or fiducials arranged on the back sheet. Fiducials are circuit pattern recognition marks that allow automated assembly equipment to accurately locate and place components on the back sheet.

Reference points are used to determine the offset of the virtual map and the real form of the back sheet. The reference points are detected for example by optical recognition means such as a camera and corresponding software in the assembly cell.

The virtual map and the first corrections are based on the measured back sheet information. The photovoltaic cell or all photovoltaic cells to be assembled can also be measured to further enhance the virtual map data. The virtual map information relating to the sheet of encapsulant material and the amount and shape of interconnecting paste may be optimized to feature the best position possible. If a large difference exists between the photovoltaic cell and the corresponding contact pad in the back sheet, it may be compensated by a larger hole and larger amount of the interconnecting paste. On the other hand, the size of the contact pad may be reduced by more accurate positioning of the photovoltaic module. The system may comprise information about more than one cell and adapt the placement to further optimize the placement of the overall module assembly.

The initial information to be used with the virtual map may be received from the design software according to prior art. The software for correcting the virtual map may be implemented in the computer controlling an assembly cell or simultaneously multiple assembly cells. The software may also be stored in or executed from a general purpose computer residing in a cloud computing environment.

The virtual map enables multiple parallel assembly cells that are configured to access the virtual map data. Different components are in one embodiment manufactured simultaneously in different locations. The virtual references are correlated to actual references, either mechanical or visual, that allow combining of all subassemblies into the completed module. The use of a virtual map allows positional variance for each solar cell and the corresponding interconnecting paste and the hole in the sheet of encapsulant material so that all of these align in the final product with high accuracy. The virtual map allows very fast cycle times when assembly cells or sub-cells have the virtual map data about the positions for each component before the previous manufacturing step has been completed. There is no need to wait for the information from the positioning system. The parallel assembly shortens the length of the line, which leads to a smaller manufacturing footprint installation and faster production cycles of the modules. This increases the flexibility and makes starting and stopping the line easier and faster.

The use of virtual references reduces or eliminates the need to have registration marks in the back sheet, and enables using opaque encapsulant material. The alignment fiducials or fiduciary markers may be either covered or not used at all during the assembly process.

In one example according to the invention the assembly is started simultaneously in multiple assembly cells. One cell can apply the interconnection material at the same time as the cells are placed onto the positions according to the virtual map. The assembly is started from the cover sheet such as glass. The glass is placed into the desired position by detecting the locations of edges or corners. The virtual map is corrected in relation to the glass cover in a manner that all components fit onto the glass plate. When the assembled module is already the protective top cover facing down, there is no need to flip the semi-assembled module or preheat it before entering the final lamination step.

The position of each cell and the related point of the sheet of encapsulant material are determined according to the virtual map information. A second sheet of encapsulant material is placed on the cover sheet. Photovoltaic cells are placed on the location indicated by the virtual map on top of the outer sheet of encapsulant material.

Simultaneously, the holes are machined to the first sheet of encapsulant material. The virtual map is corrected to position the holes between the electrical connectors and corresponding interconnecting paste and the connectors of the photovoltaic cells.

After all sub-assemblies are completed they are assembled in a single location using accurate positioning tools. Heat may be applied to fix all components in place. The completed assembly is then moved to the laminating machine, where air is removed from the assembly and heat is applied, allowing the encapsulant material to flow and fill all gaps in the assembly. The heat applied, in the laminating process solidifies the interconnection material. Alternatively a separate process may be used to ensure good electrical contact between the contacts on the photovoltaic cells and the conductors on the back sheet.

Embodiments of the present invention comprising for example control logic of the manipulator may be implemented in software, hardware, application logic or a combination of software, hardware and application logic. In an example embodiment, the application logic, software or instruction set is maintained on any one of various conventional computer-readable media. In the context of this document, a “computer-readable medium” may be any media or means that can contain, store, communicate, propagate or transport the instructions for use by or in connection with an instruction execution system, apparatus, or device, such as a computer. A computer-readable medium may comprise a computer-readable storage medium that may be any media or means that can contain or store the instructions for use by or in connection with an instruction execution system, apparatus, or device, such as a computer. The exemplary embodiments can store information relating to various processes described herein. This information can be stored in one or more memories, such as a hard disk, optical disk, magneto-optical disk, RAM, and the like. One or more databases can store the information used to implement the exemplary embodiments of the present inventions. The databases can be organized using data structures (e.g., records, tables, arrays, fields, graphs, trees, lists, and the like) included in one or more memories or storage devices listed herein. The processes described with respect to the exemplary embodiments can include appropriate data structures for storing data collected and/or generated by the processes of the devices and subsystems of the exemplary embodiments in one or more databases.

All or a portion of the exemplary embodiments can be conveniently implemented using one or more general purpose processors, microprocessors, digital signal processors, micro-controllers, and the like, programmed according to the teachings of the exemplary embodiments of the present inventions, as will be appreciated by those skilled in the computer and/or software art(s). Appropriate software can be readily prepared by programmers of ordinary skill based on the teachings of the exemplary embodiments, as will be appreciated by those skilled in the software art. In addition, the exemplary embodiments can be implemented by the preparation of application-specific integrated circuits or by interconnecting an appropriate network of conventional component circuits, as will be appreciated by those skilled in the electrical art(s). Thus, the exemplary embodiments are not limited to any specific combination of hardware and/or software.

If desired, the different functions discussed herein may be performed in a different order and/or concurrently with each other.

Furthermore, if desired, one or more of the above-described functions may be optional or may be combined. Although various aspects of the invention are set out in the independent claims, other aspects of the invention comprise other combinations of features from the described embodiments and/or the dependent claims with the features of the independent claims, and not solely the combinations explicitly set out in the claims.

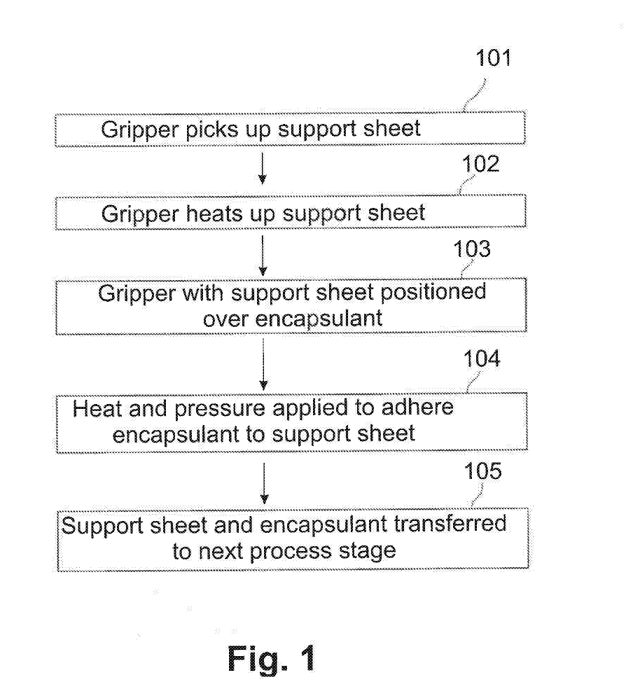

The exemplary process illustrated in FIG. 1 starts in step 101 by picking a support sheet by a gripper, e.g. a vacuum gripper. The support sheet can be the back sheet or the cover sheet of the photovoltaic module. Next, in step 102, the gripper heats up the support sheet to a temperature sufficient to make the encapsulant material of the sheet of encapsulant material to adhere to the heated support sheet. In step 103, the gripper with the support sheet is positioned over the sheet of encapsulant material. In the case where the positioning is strictly defined, the positioning can be carried out e.g. by using a virtual map containing the positioning information. In step 104, the gripped support sheet is controlled so as to bring the heated support sheet into contact with the sheet of encapsulant material, wherein heat and pressure is applied to adhere the sheet of encapsulant material to the support sheet. Finally, in step 105, the entire sub-assembly of the support sheet and the sheet of encapsulant material is transferred to the next process stage.

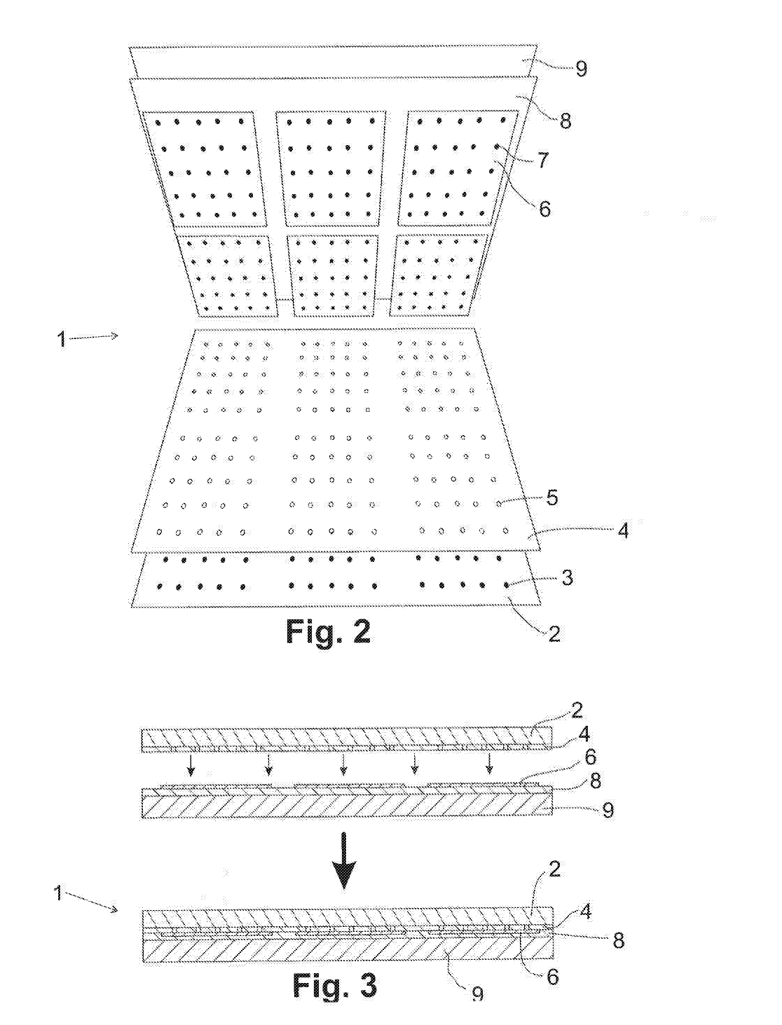

The exploded view of FIG. 2 shows the five essential layers of the photovoltaic module 1: a back sheet 2 having contact pads 3 thereon; a first sheet of encapsulant material 4 having interconnecting holes 5 therein; an array of photovoltaic cells 6, each having an array of contacts 7 on the back side of the cell; a second sheet of encapsulant material 8; and a transparent cover sheet 9 made of e.g. glass. The exploded view illustrates the importance of accurate positioning of the back sheet, the first sheet of encapsulant, and the array of the photovoltaic cells: the contacts of the cells, the holes in the first sheet of encapsulant material, and the contact pads of the back sheet must coincide in order to form the appropriate electrical connections.

FIG. 3 illustrates the handling of the thin sheets of encapsulant material by means of a heated support sheet. In the example of FIG. 3, the parts of the photovoltaic module are the same as those in FIG. 2. The layer stack of the photovoltaic module 1 is assembled upside down on the cover sheet 9, wherein the side configured to receive the light is facing down. When the second sheet of encapsulant material 8 and the array of photovoltaic cells have been stacked on the cover sheet, the first sheet of encapsulant 4 is handled and brought on the stack by being gripped by a heated back sheet 2 to which the encapsulant material has been adhered. In other words, the back sheet is used as a support sheet for handling the first sheet of encapsulant. Though not shown in the figure, also the second sheet of encapsulant material can be handled similarly, using the cover sheet as a heated support sheet.

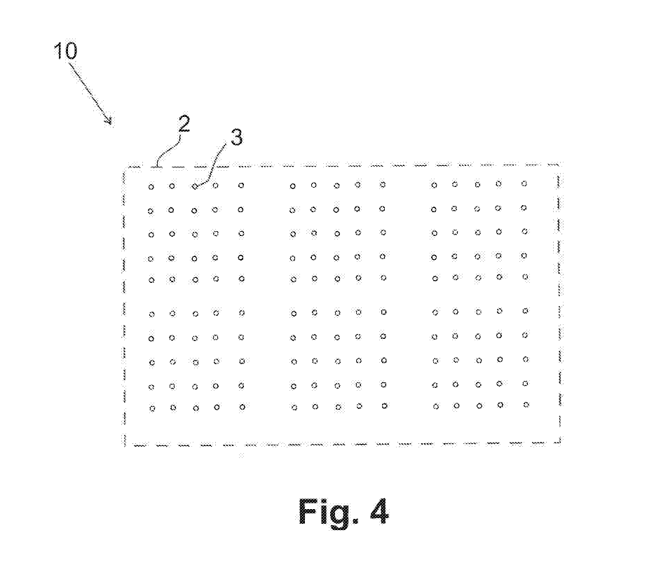

FIG. 4 illustrates an example of a virtual map 10 defining the dimensions of the back sheet 2 and the locations of the contact pads 3 thereon. The virtual map can be used for accurate positioning of the parts of the module, in particular the photovoltaic cells and the first sheet of encapsulant material so that the electrical interconnections between the cell contacts and the contact pads of the back sheet can be formed via the interconnecting holes of the first sheet of encapsulant material. The actual electrical connections between the contact pads and the cell contact are formed by means of a conductive paste, solder paste or some other suitable conductive material (not shown in the figures).

In FIGS. 2 to 4, for the sake of clarity of the drawings, the exemplary photovoltaic module comprises only 6 photovoltaic cells. However, in practice, the photovoltaic module may comprise any appropriate number of photovoltaic cells. Typically, a photovoltaic module comprises some tens of photovoltaic cells.

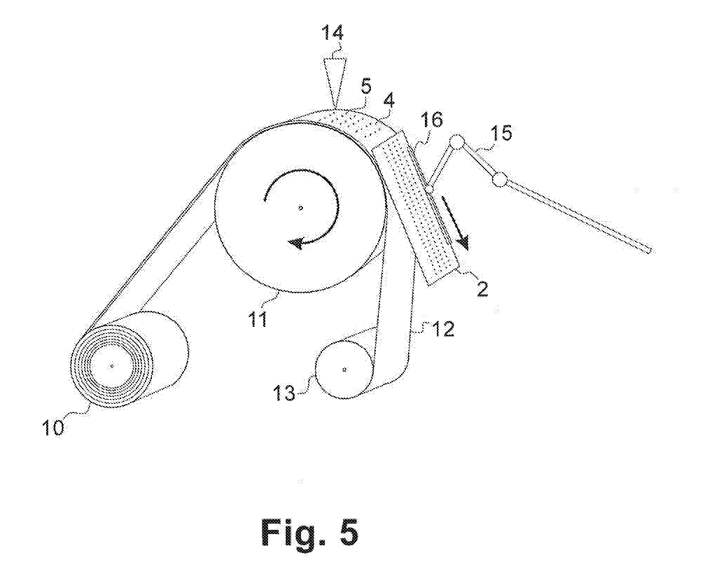

FIG. 5 illustrates a simplified example of an embodiment wherein the back sheet 2 is used to grab the sheet of encapsulant material 4 from the roller 11. The sheet of encapsulant material 4 is provided in a roll form 10. The encapsulant material 4 is on the roll 10 with a supporting liner 12 that enables easier handling of the thin film. The sheet of encapsulant material 4 along with the supporting liner 12 is carried to the rotating roller 11. The sheet of encapsulant material 4 receives holes and edges from a cutting machine 14, which is for example operated by a laser. The manipulator 15 places the back sheet 2 to the exact position according to the virtual map information, aligning the electrical connections and holes of the sheet of encapsulant material 4. The manipulator 15 moves the pre-heated back sheet 2 along the roller 11, causing the sheet of encapsulant material 4 to adhere to the back sheet 2. The back sheet may be heated as a whole or only partially, for example by a heater 16 arranged to the manipulator 15. The remaining supporting liner 12 is collected to roll 13, thus keeping the supporting liner 12 tight during the whole procedure.

It is obvious to a person skilled in the art that with the advancement of technology, the basic idea of the invention may be implemented in various ways. The invention and its embodiments are thus not limited to the examples described above; instead they may vary within the scope of the claims. In particular, it is to be noted that the above examples are focused on specific situations wherein the connections of the photovoltaic cells are made via the back sheet comprising appropriate circuit elements, the lower sheet of encapsulant comprising corresponding holes for the interconnections; the placement of the elements of the photovoltaic cell is based on virtual mapping; and the back sheet is used as the heated support sheet. It is to be noted that, however, the basic principle of utilizing a heated support sheet applies also to the assembly of a conventional photovoltaic module wherein the back sheet has no conductive circuit elements and the sheet of encapsulant between the back sheet and the photovoltaic cells has thus no holes. Also, the basic principle of using a heated support sheet is not dependent on the way of positioning the elements of the photovoltaic module and is thus not limited to those cases only where the positioning is based on a virtual map. Finally, irrespective of the basic configuration of the photovoltaic module and the way of carrying out the positioning of the elements thereof, also the cover sheet can be used as a heated support sheet. In that case, the sheet of encapsulant which is gripped by the heated support sheet is the sheet of encapsulant between the photovoltaic cells and the cover sheet.

1. A method of assembling a photovoltaic module comprising:
a back sheet;
a cover sheet; and
a multitude of photovoltaic cells between the back sheet and the cover sheet, the photovoltaic cells being separated from the back sheet and the cover sheet by sheets of encapsulant material,
characterized by the method comprising:
using at least one of the back sheet and the cover sheet as a support sheet;
heating at least portion of the support sheet to a temperature suitable for the encapsulant material to adhere to the support sheet; and
moving the support sheet to be in contact with one of the sheets of encapsulant material, causing the sheet of encapsulant material to adhere to the support sheet.

2. The method according to claim 1, characterized by lifting the sheet of encapsulant material from the work plane by lifting the support sheet.

3. The method according claim 1, characterized by lifting the sheet of encapsulant material from the roller by moving the support sheet along the roller.

4. The method according to claim 3, characterized by separating the sheet of encapsulant material from the supporting liner during lifting the support sheet from the roller, causing the sheet of encapsulant material to retain same dimensions as being attached to the supporting liner.

5. The method according to claim 1, characterized by comprising:
using the back sheet as the support sheet;
forming a virtual map containing the assembly positions of the back sheet and the sheet of encapsulant material separating the back sheet and the plurality of photovoltaic cells;
machining holes to said sheet of encapsulant material according to the virtual map; and
positioning the back sheet on top of the sheet of encapsulant material having the holes therein according to the virtual map position information.

6. A system for assembling a photovoltaic module comprising:
a back sheet;
a cover sheet; and
a multitude of photovoltaic cells between the back sheet and the cover sheet, the photovoltaic cells being separated from the back sheet and the cover sheet by sheets of encapsulant material,
characterized by the system comprising:
means for heating at least a portion of a support sheet, at least one of the back sheet and the cover sheet arranged to be used as the support sheet, to a temperature suitable for the encapsulant material to adhere to the support sheet; and
means for moving the support sheet to be in contact with one of the sheets of encapsulant material, causing the sheet of encapsulant material to adhere to the support sheet.

7. The system according to claim 6, characterized by comprising means for lifting the sheet of encapsulant material from the work plane by lifting the support sheet.

8. The system according to claim 6, characterized by comprising means for lifting the sheet of encapsulant material from the roller by moving the support sheet along the roller.

9. The system according to claim 8, characterized by comprising means for separating the sheet of encapsulant material from the supporting liner during lifting the support sheet from the roller, causing the sheet of encapsulant material to retain same dimensions as being attached to the supporting liner.

10. The system according to claim 6, characterized by using the back sheet as the support sheet, the system comprising:
means for forming a virtual map comprising the assembly positions of the back sheet and the sheet of encapsulant material separating the back sheet and the plurality of photovoltaic cells;
means for machining holes to said sheet of encapsulant material to positions according to the virtual map; and
means for positioning the back sheet on top of the sheet of encapsulant material having the holes therein according to the virtual map position information.
